(19) United States
(12) Patent Application Publication
(10) Pub. No.: US 2009/0047447 A1
(43) Pub. Date: Feb. 19, 2009

(54) Method for removing surface deposits and passivating interior surfaces of the interior of a chemical vapor deposition reactor

(76) Inventors: Herbert H. Sawin, Chestnut Hill, MA (US); Bo Bai, Cambridge, MA (US); Ju Jin An, Cambridge, MA (US)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(21) Appl. No.: 11/497,790

(22) Filed: Aug. 2, 2006

Related U.S. Application Data
(60) Provisional application No. 60/704,852, filed on Aug. 2, 2005.
(60) Provisional application No. 60/704,840, filed on Aug. 2, 2005.
(60) Provisional application No. 60/736,430, filed on Nov. 14, 2005.
(60) Provisional application No. 60/779,470, filed on Mar. 6, 2006.

(51) Int. Cl. C23C 16/511; C23C 16/513; C09K 3/00; B08B 5/00; C11D 3/02; C11D 3/16; C11D 3/20

(52) U.S. Cl. 427/575; 427/569; 118/723 R; 134/1.1; 252/372; 510/108; 510/461; 510/505

(57) ABSTRACT

The present invention relates to plasma cleaning methods for removing surface deposits from a surface, such as the interior of a depositions chamber that is used in fabricating electronic devices. The present invention also provides gas mixtures and activated gas mixtures which provide superior performance in removing deposits from a surface. The methods involve activating a gas mixture comprising a carbon or sulfur source, NF₃, and optionally, an oxygen source to form an activated gas, and contacting the activated gas mixture with surface deposits to remove the surface deposits wherein the activated gas mixture acts to passivate the interior surfaces of the apparatus to reduce the rate of surface recombination of gas phase species.

### FIELD OF THE INVENTION

The present invention relates to methods for removing surface deposits by using an activated gas mixture created by activating a gas mixture that includes a nitrogen source, a carbon or sulfur source, and a optionally, an oxygen source, as well as the gas mixtures and activated gases used in these methods.

### BACKGROUND OF THE INVENTION

One of the problems facing the operators of chemical vapor deposition reactors is the need to regularly clean the chamber to remove deposits from the chamber walls and platens. This cleaning process reduces the productive capacity of the chamber since the chamber is out of active service during a cleaning cycle. The cleaning process may include, for example, the evacuation of reactant gases and their replacement with an activated cleaning gas followed by a flushing step to remove the cleaning gas from the chamber using an inert carrier gas. The cleaning gases typically work by etching the contaminant build-ups from the interior surfaces, thus the etching rate of the cleaning gas is an important parameter in the utility and commercial use of the gases. Present cleaning gases are believed to be limited in their effectiveness due to low etch rates. In order to partially obviate this limitation, current gases need to be run at an inefficient flow rate, e.g. at a high flow rate, and thus greatly contribute to the overall operating cost of the CVD reactor. In turn this increases the production cost of CVD wafer products. Further attempts at increasing the pressure of the gases to increase the etch rates have instead resulted in lower etch rates. This is most likely due to the loss of gas phase species due to increased recombination at the increased pressures. For example, Kastenmeier, et al. in Journal of Vacuum Science & Technology A 16 (4), 2047 (1998) disclose etching silicon nitride in a CVD chamber using a mixture of NF₃ and oxygen as a cleaning gas. K. J. Kim et al, in Journal of Vacuum Science & Technology B 22 (2), 483 (2004) disclose etching silicon nitride in a CVD chamber adding nitrogen or argon to mixtures of perfluorotetrahydrofuran and oxygen. U.S. Pat. No. 6,449,521 discloses a mixture of 54% oxygen, 40% perfluoroethane and 6% NF₃ as a cleaning gas for cleaning silicon dioxide deposits from CVD chambers. Thus, there is a need in the art to reduce the operating costs of a CVD reactor with an effective cleaning gas capable of lowering the overall operating cost of the CVD chamber.

### BRIEF SUMMARY OF THE INVENTION

The present invention provides effective methods for removing surface deposits from the interior of a CVD reactor using novel cleaning gas mixtures and activated cleaning gas mixtures. The methods of the invention include, but are not limited to, the steps of providing a gas mixture, activating the gas mixture in a remote chamber or in a process chamber to form an activated gas mixture, where the gas mixture comprises a source of at least one atom selected from the group consisting of carbon and sulfur, NF₃, and optionally, an oxygen source, wherein the molar ratio of oxygen:carbon source is at least 0.75:1; and contacting the activated gas mixture with surface deposits within the CVD reactor. The gas mixtures of the present invention include, but are not limited to, at least one inorganic fluorine source, a carbon source gas or a sulfur source, at least one nitrogen source, and optionally at least one oxygen source. The activated gas mixtures produced from the gas mixtures include but are not limited to mixtures of fluorine atoms, nitrogen atoms, at least one atom selected from the group consisting of carbon and sulfur, and optionally oxygen. In one embodiment of the invention, the activated gas mixture comprises (on a moles of atoms basis), from about 60% to about 75% fluorine atoms, from about 10% to about 30% nitrogen atoms, optionally from about 0.4% to about 15% oxygen atoms, and from about 0.3% to about 15% at least one atom selected from the group consisting of carbon and sulfur, optionally including a carrier gas.

### BRIEF DESCRIPTION OF THE DRAWINGS

FIG. 1 is a schematic diagram of an apparatus useful for carrying out the present process.

FIG. 2 is a schematic diagram of another apparatus useful for carrying out the present process.

FIG. 3 is a plot of silicon nitride etching rate for various compositions at a process chamber pressure of 5 torr and different wafer temperatures

FIG. 4 is a plot of silicon nitride etching for various compositions at a process chamber pressure of 2 torr, as a function of plasma source pressure.

FIG. 5 is a plot of silicon nitride etching for various compositions at a process chamber pressure of 3 torr, as a function of plasma source pressure.

FIG. 6 is a plot of silicon nitride etching for various compositions at a process chamber pressure of 5 torr, as a function of plasma source pressure.

FIG. 7 is a plot of silicon nitride etching at different temperatures at a process chamber pressure of 2 torr, as a function of plasma source pressure.

FIG. 8 is a plot of silicon nitride etching at different temperatures at a process chamber pressure of 3 torr, as a function of plasma source pressure

FIG. 9 is a plot comparing silicon nitride etching rates using C₂F₆ and C₄H₈ as the fluorocarbon at a remote chamber pressure of 2 torr.

FIG. 10 is a plot comparing silicon nitride etching rates using C₂F₆ and C₄H₈ as the fluorocarbon at a process chamber pressure of 3 torr.

FIG. 11 is a plot comparing silicon nitride etching rates using C₂F₆, oxygen, and NF₃ at a flow rate of 4800 sccm at a process chamber pressure of 5 torr at different wafer temperatures.

FIG. 12 is a plot of silicon nitride etching with different gas compositions using NF₃ and carbon dioxide at a process chamber pressure of 5 torr.

FIG. 13 is a plot comparing silicon nitride etching rates using C₂F₆ and CH₄ as the carbon source gasses.

FIG. 14 is a plot illustrating nitride etch rates as a function of process chamber pressure comparing different gas compositions.

FIG. 15 is a plot illustrating nitride etch rates as a function of process chamber pressure comparing different gas compositions.

### DETAILED DESCRIPTION OF THE INVENTION

Surface deposits as referred to herein comprise those materials commonly deposited by chemical vapor deposition (CVD), plasma-enhanced chemical vapor deposition (PECVD) or similar processes. Such materials include nitrogen-containing deposits. Such deposits include, without limitation, silicon nitride, silicon oxynitride, silicon carbonitride (SiCN), silicon boronitride (SiBN), and metal nitrides, such as tungsten nitride, titanium nitride or tantalum nitride. In one embodiment of the invention, the surface deposit is silicon nitride.

In one embodiment of the invention, surface deposits are removed from the interior of a process chamber that is used in fabricating electronic devices. Such a process chamber could be a CVD chamber or a PECVD chamber. Other embodiments of the invention include, but are not limited to, removing surface deposits from metals, the cleaning of plasma etching chambers and removal of N-containing thin films from a wafer.

In one embodiment, the process of the present invention involves an activating step wherein a cleaning gas mixture is activated, either in the process chamber or in the remote chamber. For the purposes of this application, activation means that at least an effective amount of the gas molecules have been substantially decomposed into their atomic species, e.g. a CF₄ gas would be activated to substantially decompose and form an activated gas (also known in the art as a plasma) comprising carbon and fluorine atoms. Activation may be accomplished by any energy input means allowing for the achievement of dissociation of a large fraction of the feed gas, such as: radio frequency (RF) energy, direct current (DC) energy, laser illumination, and microwave energy. One embodiment of the invention uses transformer coupled inductively coupled lower frequency RF power sources in which the plasma has a torroidal configuration and acts as the secondary of the transformer. The use of lower frequency RF power allows the use of magnetic cores that enhance the inductive coupling with respect to capacitive coupling; thereby allowing the more efficient transfer of energy to the plasma without excessive ion bombardment which limits the lifetime of the remote plasma source chamber interior. Typical RF power used has a frequency lower than 1000 kHz. In another embodiment of the invention the power source is a remote microwave, inductively, or capacitively coupled plasma source. In yet another embodiment of the invention, the gas is activated using glow discharge.

Activation of the cleaning gas mixture uses sufficient power for a sufficient time to form an activated gas mixture. In one embodiment of the invention the activated gas mixture has a neutral temperature of at least about 3,000 K. The neutral temperature of the resulting plasma depends on the power and the residence time of the gas mixture in the remote chamber. Under certain power input and conditions, neutral temperature will be higher with longer residence times. Under appropriate conditions (considering power, gas composition, gas pressure and gas residence time), neutral temperatures of at least about 6,000 K may be achieved.

The activated gas may be formed in a separate, remote chamber that is outside of the process chamber, but in close proximity to the process chamber. In this invention, remote chamber refers to the chamber other than the cleaning or process chamber, wherein the plasma may be generated, and the process chamber refers to the chamber wherein the surface deposits are located. The remote chamber is connected to the process chamber by any means allowing for transfer of the activated gas from the remote chamber to the process chamber. For example, the means for allowing transfer of the activated gas may comprise a short connecting tube and a showerhead of the CVD/PECVD process chamber. The means for allowing transfer of the activated gas may further comprise a direct conduit from the remote plasma source chamber to the process chamber. The remote chamber and means for connecting the remote chamber with the process chamber are constructed of materials known in this field to be capable of containing activated gas mixtures. For instance, aluminum and anodized aluminum are commonly used for the chamber components. Sometimes Al₂O₃ is coated on the interior surface to reduce the surface recombination. In other embodiments of the invention, the activated gas mixture may be formed directly in the process chamber.

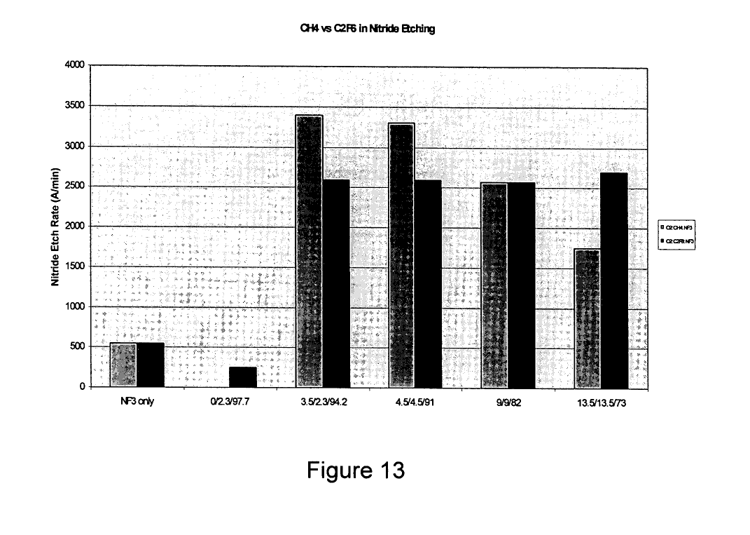

The gas mixture (that is to be activated to form the activated gas mixture) comprises at least one inorganic fluorine source, at least one source of one or more atoms selected from the group consisting of carbon and sulfur, at least one nitrogen source, and optionally at least one oxygen source. Typical inorganic fluorine sources include NF₃ and SF₆. Where SF₆ serves as the inorganic fluorine source, it can also serve as a source of sulfur. When a carbon source is used, a carbon source can be a fluorocarbon or a hydrocarbon, carbon dioxide or carbon monoxide. A fluorocarbon is herein referred to as a compound containing C and F, and optionally O and H. In one embodiment of the invention, a fluorocarbon is a perfluorocarbon or a mixture of one or more perfluorocarbons. A perfluorocarbon compound as referred to in this invention is a compound consisting of C, F and optionally oxygen. Such perfluorocarbon compounds include, but are not limited to tetrafluoromethane, hexafluoroethane, octafluoropropane, hexafluororcyclopropane, decafluorobutane, hexafluoropropene, octafluorocyclobutane and octafluorotetrahydrofuran. Without wishing to be bound by any particular theory, applicant believes that the fluorocarbon of the gas mixture serves as a source of carbon atoms in the activated gas mixture. Carbon source gasses also may include hydrofluorocarbons or hydrocarbons. In one embodiment of the invention, the hydrocarbon carbon source is methane. This was unexpected, as it is commonly held in the art that hydrogen atoms in the activated gas mixture are detrimental due to the expected recombination of F atoms with H atoms to form hydrogen fluoride (HF). This would decrease gas phase reactive F atoms concentrations as well as be deleterious to surfaces inside the apparatus. As illustrated in Example 11 (FIG. 13) adding up to 5-10% CH₄ provides increased etch rate performance compared to C₂F₆ when used as source gases with NF₃ and O₂. Typical nitrogen sources include molecular nitrogen (N₂) and NF₃. When NF₃ is the inorganic fluorine source, it can also serve as the nitrogen source. Typical oxygen sources include molecular oxygen (O₂), carbon dioxide, sulfur dioxide and sulfur trioxide. When carbon dioxide is the oxygen source, it can also serve as a carbon source. When sulfur dioxide or sulfur trioxide are the oxygen source, they can also serve as a sulfur source. When the fluorocarbon is a fluoroketone, fluoroaldehyde, fluoroether, carbonyl difluoride (COF₂) or otherwise contains an O atom, such as octafluorotetrahydrofuran, the fluorocarbon can also serve as the oxygen source. In one embodiment of the invention, the oxygen:fluorocarbon molar ratio is at least 0.75:1. In another embodiment of the invention, the oxygen:fluorocarbon molar ratio is at least 1:1. Depending on the fluorocarbon chosen, in other embodiments of the invention the oxygen:fluorocarbon molar ratio may be 2:1.

In one embodiment of the invention, the percentage on a molar basis of inorganic fluorine source in the gas stream is from about 50% to about 98%. In another embodiment of the invention the percentage on a molar basis of inorganic fluorine source in the gas stream is from about 60% to about 98%. In yet another embodiment of the invention, the percentage on a molar basis of inorganic fluorine source in the gas stream is from about 70% to about 90%. In yet another embodiment of the invention, when NF₃ is the source for nitrogen and fluorine and carbon dioxide is the carbon and oxygen source, the percentage on a molar basis of carbon dioxide in the gas stream is from about 2% to about 15%. The gas mixture may further comprise a carrier gas. Examples of suitable carrier gasses include noble gasses such as argon and helium.

In one embodiment, the activated gas mixture contains from about 66% to about 87% fluorine atoms. In one embodiment, the activated gas mixture contains from about 11% to about 24% nitrogen atoms. In one embodiment, the activated gas mixture contains from about 0.9% to about 11% oxygen atoms. In one embodiment, the activated gas mixture contains about 0.6% to about 11% carbon atoms, 0.6% to about 11% sulfur atoms, or mixtures thereof.

In one embodiment of the invention, the activated gas mixture includes from about 66% to about 74% fluorine atoms, from about 11% to about 24% nitrogen atoms, from about 0.9% to about 11% oxygen atoms, and from about 0.6% to about 11% carbon atoms.

In an embodiment of the invention, the temperature in the process chamber during removal of the surface deposits often may be from about 50° C. to about 200° C. Depending on the location within the apparatus, surface temperatures however may range as high as 400° C.

The total pressure in the remote chamber during the activating step may be between about 0.5 torr and about 15 torr using the Astron source. The total pressure in the process chamber may be between about 0.5 torr and about 15 torr. With other types of remote plasma sources or in situ plasma sources, the maximum pressure can be reduced.

It has been found that the combination of an inorganic fluorine source, a nitrogen source, and at least one source of an atom selected from the group consisting of carbon and sulfur, and optionally an oxygen source, results in significantly higher etching rates of nitride films such as silicon nitride. These increases also provide lower sensitivity of the etch rate to variations in source gas pressure, chamber pressure and temperature. Without wishing to be bound by any particular theory, applicant theorizes that a combination of activated gas phase species act to passivate the interior surfaces of the apparatus to significantly reduce the rate of surface recombination of gas phase species, thereby preventing the loss of species after activation. In addition to providing higher etch rates over a wider range of pressures than has been able to be utilized heretofore, it has been found that this also provides significantly enhanced cleaning of the downstream components of the apparatus due to the reduced rate of recombination of gas phase species.

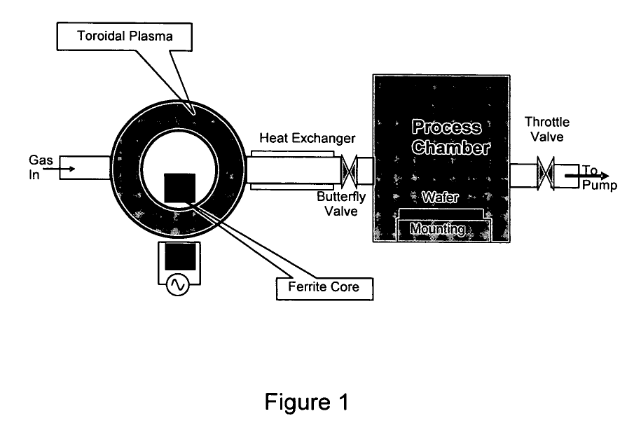

FIG. 1 shows a schematic diagram of a remote plasma source and apparatus used to measure the etching rates, plasma neutral temperatures, and exhaust emissions. The remote plasma source is a commercial toroidal-type MKS ASTRON®ex reactive gas generator unit make by MKS Instruments, Andover, Mass., USA.

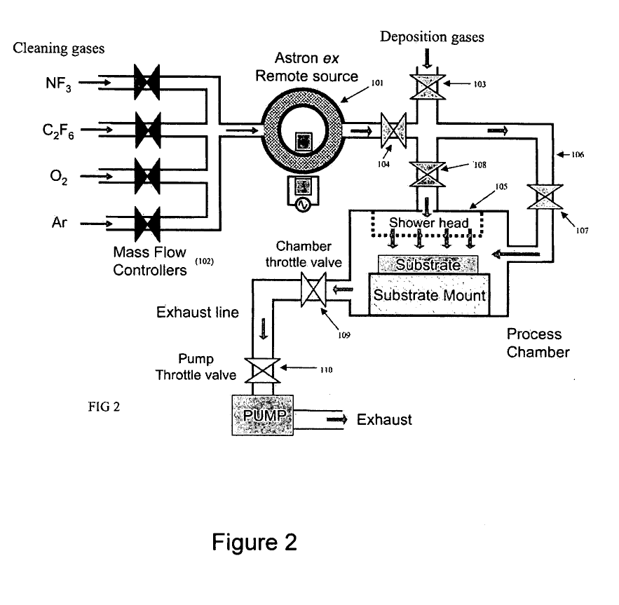

Shown in FIG. 2 is another embodiment in which the cleaning gases are mixed using mass flow controller, 102, in this case NF₃, C₂F₆, and O₂; however, other mixtures may be used. Argon is included to facilitate starting of the Astron®ex source, 101, and can be added during the cleaning process as well. An Astron®ex is used in this example, however other remote source may be used. During chamber cleaning, the deposition gases are blocked by valve 103. The output of the remote plasma source is directed to the chamber through an optional flow restricting device, 104, through the showerhead, 105, which serves as a conduit into the process chamber, 100, and/or directly to the process chamber through a direct conduit, 106. The flow restricting device can be an orifice or a valve. By use of valves 107 and 108 to vary the direct flow of part or all of the activated gas to the process chamber, the pressure drop and loss of reactant species in the shower head can be reduced allowing greater cleaning rates of the chamber. Combinations of flows through the showerhead, and into the chamber bypassing the showerhead, can be tailored during the cleaning process to optimize the cleaning of the deposits which are peculiar to the particular chamber and process conditions used during the PECVD process. Although the substrate is shown on the mount, it is typically not present during cleaning of the chamber.

By throttling the flow from the chamber and to the pump using one or more throttle valves, 109 and 110, the process chamber can be controlled to control the partial pressure of the reactant during the cleaning process in the process chamber and/or in the exhaust line between the chamber and the pump. Using this invention, it has been demonstrated that the reduced loss rate of reactants by surface recombination allows the increase in cleaning gas pressure without excessive loss of the reactants. The higher partial pressure of the reactant gases can increase the cleaning rate and efficiency. The number, positions, and setting of the throttle valves 109 and 110 can be adjusted before or during the cleaning process to optimize the cleaning of the process chamber and pump exhaust (fore) line. Shown in this example is the use of two throttle valves; however one or more valves may be used. The settings of these valves to optimize the cleaning of the deposits are peculiar to the particular chamber and process conditions used during the PECVD process as well as a function of the temperature of the surfaces and other particulars of the system, but can readily be determined by one of ordinary skill in the art without undue experimentation.

As a result of the reduced dependence of etch rate on pressure and temperature, it is possible to operate the apparatus during the cleaning cycle at a lower temperature, thereby reducing the loss of gas phase species through recombination on interior surfaces and increasing etching rates, and cleaning of exhaust piping between the chamber and the pump.

The following Examples are meant to illustrate the invention and are not meant to be limiting.

### EXAMPLES

The feed gases (e.g. O₂, fluorocarbon, NF₃ and carrier gas) were introduced into the remote plasma source from the left, and passed through the toroidal discharge where they were discharged by the 400 kHz radio-frequency power to form an activated gas mixture. The oxygen is manufactured by Airgas with 99.999% purity. The fluorocarbon in the examples is either Zyron® 8020 manufactured by DuPont with a minimum 99.9 vol. % of octafluorocyclobutane or Zyron® 116 N5 manufactured by DuPont with a minimum 99.9 vol. % of hexafluoroethane. The NF₃ gas is manufactured by DuPont with 99.999% purity. Argon is manufactured by Airgas with a grade of 5.0. Typically, Ar gas is used to ignite the plasmas, after which time flows for the feed gases were initiated, after Ar flow was halted. The activated gas mixture then is passed through an aluminum water-cooled heat exchanger to reduce the thermal loading of the aluminum process chamber. The surface deposits covered wafer was placed on a temperature controlled mounting in the process chamber. The neutral temperature is measured by Optical Emission Spectroscopy (OES), in which rotovibrational transition bands of diatomic species like C₂ and N₂ are theoretically fitted to yield neutral temperature. See also B. Bai and H Sawin, Journal of Vacuum Science & Technology A 22 (5), 2014 (2004), which is herein incorporated by reference. The etching rate of surface deposits by the activated gas is measured by interferometry equipment in the process chamber. N₂ gas is added at the entrance of the exhaustion pump both to dilute the products to a proper concentration for FTIR measurement and to reduce the hang-up of products in the pump. FTIR was used to measure the concentration of species in the pump exhaust.

### Example 1

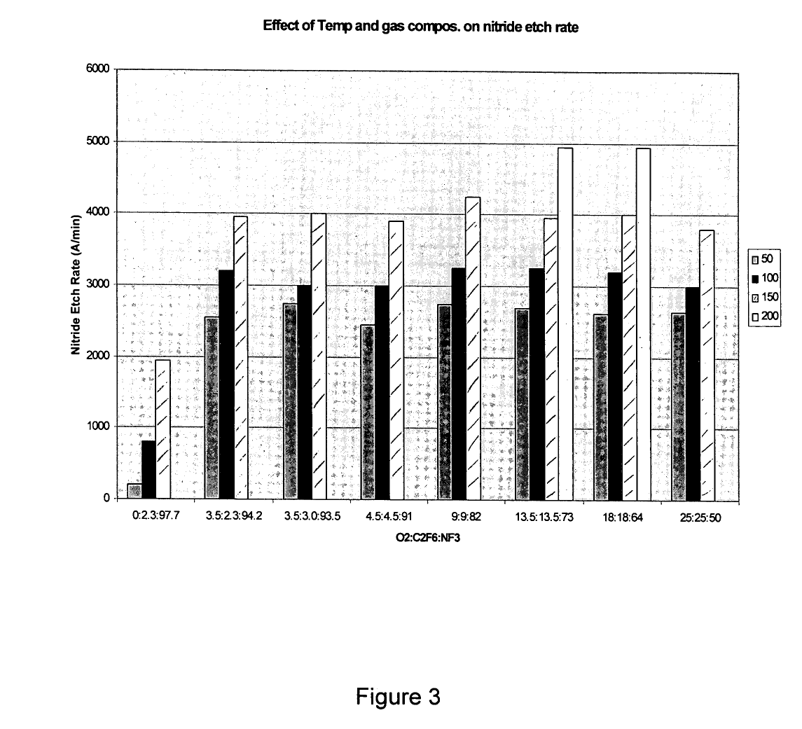

This example illustrates the effect of the addition of fluorocarbon on the silicon nitride etch rate in NF₃ systems with oxygen at different gas compositions and different wafer temperatures. In this experiment, the feed gas was composed of NF₃, oxygen and C₂F₆. Process chamber pressure was 5 torr. Total gas flow rate was 1700 sccm, with flow rates for the individual gases set proportionally as required for each experiment. By way of illustration, in the experiment with 9% oxygen, 9% C₂F₆, and 82% NF₃, the oxygen flow rate was 150 sccm, the C₂F₆ flow rate was 150 sccm, and the NF₃ flow rate was 1400 sccm. The feeding gas was activated by the 400 kHz 5.9-8.7 kW RF power. The activated gas then entered the process chamber and etched the silicon nitride surface deposits on the mounting with the temperature controlled at 50° C. As shown in FIG. 3, when 3.5 mole percent oxygen and 2.3 mole percent fluorocarbon were added, the etch rate was over 2500 A/min, and exhibited low sensitivity to variations in the amounts of fluorocarbon and oxygen addition. The same phenomena were observed in all wafer temperatures tested: 50° C., 100° C., 150° C. and 200° C.

### Example 2

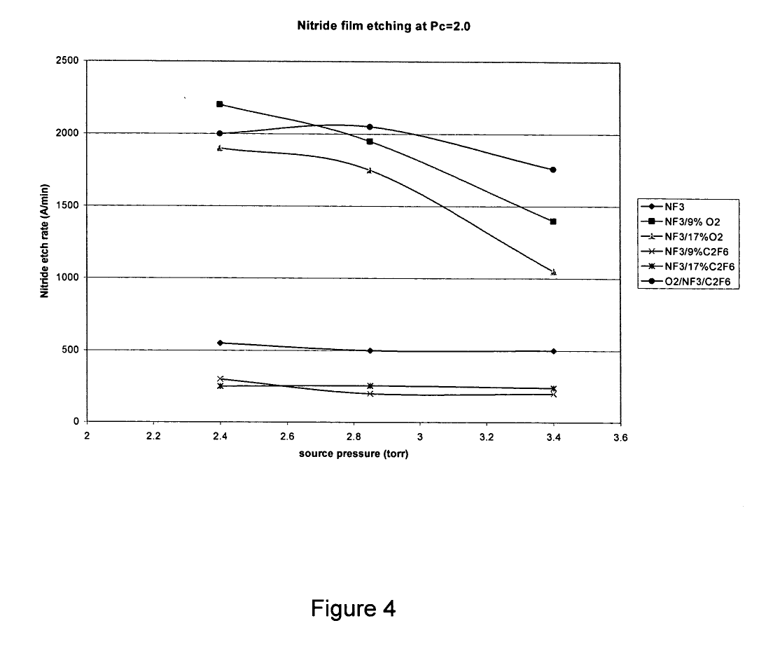

This example illustrated the effect of the addition of fluorocarbon on the silicon nitride etch rate in NF₃ systems with oxygen and the reduced effect of source pressure on etch rate. The results are illustrated in FIG. 4. In this experiment, the feed gas was composed of NF₃, optionally with O₂ and optionally with C₂F₆. Process chamber pressure was 2 torr. Total gas flow rate was 1700 sccm, with flow rates for the individual gases set proportionally as required for each experiment. By way of illustration, in the experiment with 9% oxygen and 91% NF₃, the NF₃ flow rate was 1550 sccm and the oxygen flow rate was 150 sccm. The feeding gas was activated by the 400 kHz 5.0˜9.0 kW RF power to a neutral temperature of more than 3000 K. The activated gas then entered the process chamber and etched the silicon nitride surface deposits on the mounting with the temperature controlled at 50° C. As shown in FIG. 3, when 9 mole percent fluorocarbon and 9 mole percent oxygen were added to NF₃, high etching rates for silicon nitride were obtained, and the rate exhibited very low sensitivity to variations in source pressure.

### Example 3

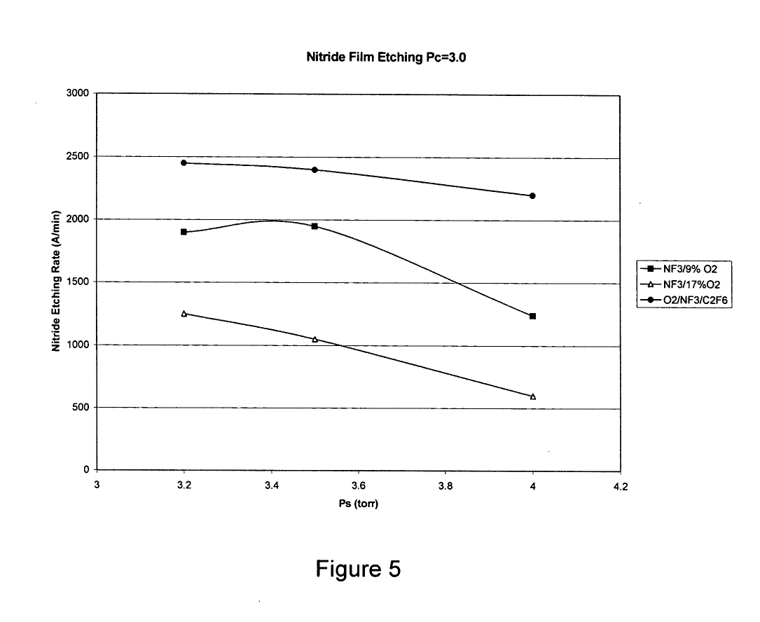

This example illustrates the effect of the addition of C₂F₆ on the silicon nitride etch rate in mixtures of NF₃ and oxygen with a chamber pressure of 3.0 torr. Total gas flow rate was 1700 sccm. The results are illustrated in FIG. 5. The feeding gas was activated by the 400 kHz 4.6 Kw RF power to a neutral temperature of more than 3000 K. As the results indicate, when 9 mole percent C₂F₆ is added to the feed gas, i.e. the feed gas mixture was composed of 9 mole percent C₂F₆, 9 mole percent oxygen and 82 mole percent NF₃, the etching rate of silicon nitride increase to from about 2200 A/min to about 2450 A/min, and exhibited lower variation with variations in source pressure.

### Example 4

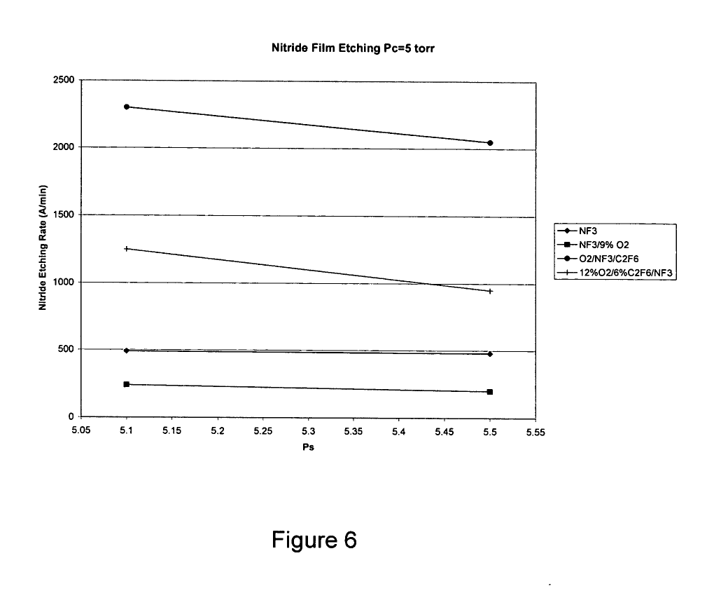

This example illustrates the effect of the addition of C₂F₆ on the silicon nitride etch rate in mixtures of NF₃ and oxygen and variations in the molar ratio of C₂F₆ to oxygen with a chamber pressure of 5.0 torr. Total gas flow rate was 1700 sccm. The results are illustrated in FIG. 6. The feeding gas was activated by the 400 kHz RF power to a neutral temperature of more than 3000 K. It was found that the highest etch rate and low variation with variations in source pressure were obtained with an oxygen to C₂F₆ ratio of 1:1. That is, with a feed gas mixture of 9 mole percent C₂F₆, 9 mole percent oxygen, and 82 mole percent NF₃. Silicon nitride etch rates with this feed gas composition were from about 2050 to about 2300 A/min compared to from about 950 A/min to about 1250 A/min with a oxygen:fluorocarbon ratio of 2:1.

### Example 5

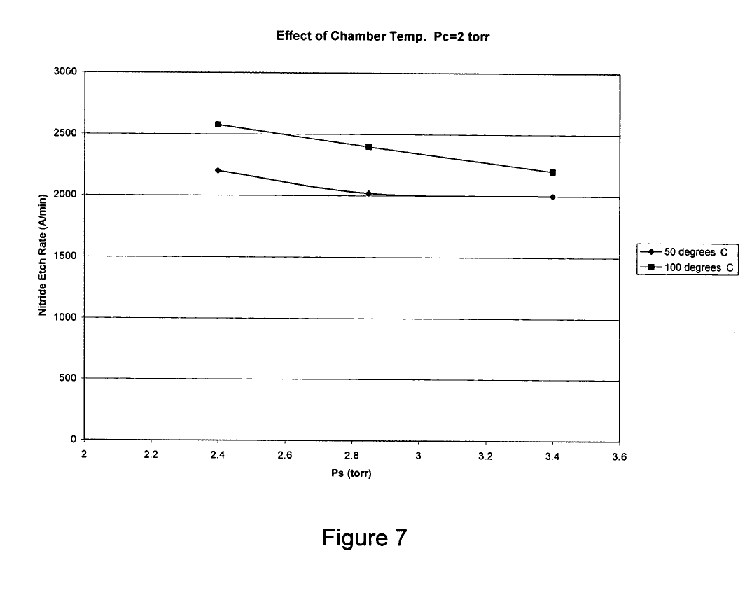

This example illustrates the effect of process chamber temperature on silicon nitride etch rate using a feed gas mixture of 9 mole percent C₂F₆, 9 mole percent oxygen, and 82 mole percent NF₃ and a chamber pressure of 2 torr. Total gas flow rate was 1700 sccm. The results are illustrated in FIG. 7. The feeding gas was activated by the 400 kHz 6.0˜6.6 kW RF power to a neutral temperature of more than 3000 K. It was found that etch rate increases somewhat as the chamber temperature is increased from 50° C. to 100° C. No significant difference in this trend was observed with changes is source pressure.

### Example 6

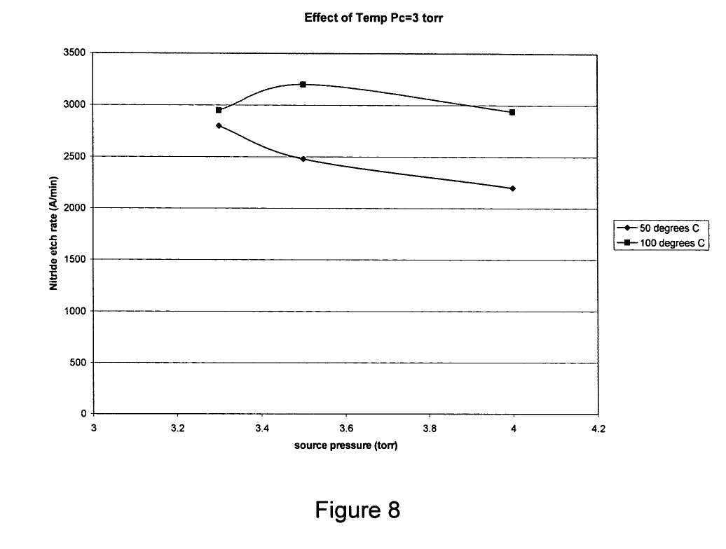

This example illustrates the effect of process chamber temperature on silicon nitride etch rate using a feed gas mixture of 9 mole percent C₂F₆, 9 mole percent oxygen, and 82 mole percent NF₃ and a chamber pressure of 3 torr. Total gas flow rate was 1700 sccm. The results are illustrated in FIG. 8. The feeding gas was activated by the 400 kHz 6.7˜7.2 kW RF power to a neutral temperature of more than 3000 K. It was found that etch rate increases somewhat as the chamber temperature is increased from 50° C. to 100° C. At 100° C. there is little variation in etch rate with changes in source pressure.

### Example 7

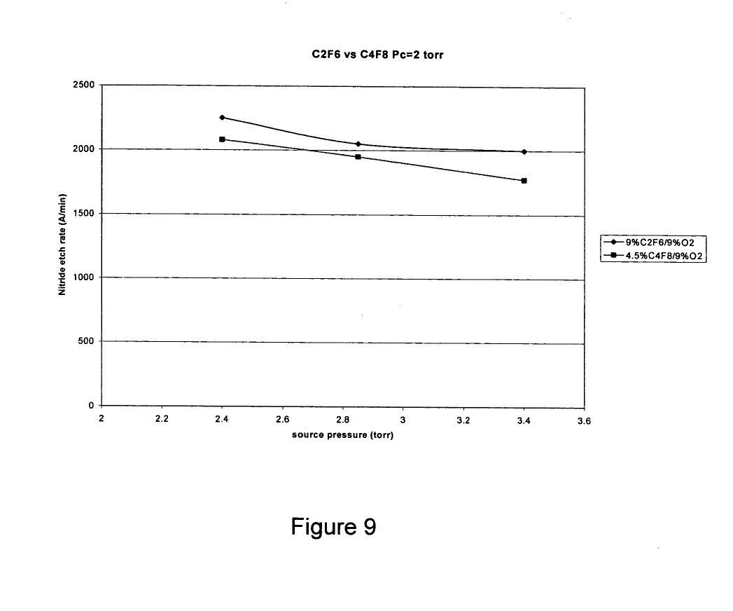

This example compares nitride etching using octafluorocyclobutane as the fluorocarbon. In this example, the feed gas mixtures were either 9 mole percent C₂F₆, 9 mole percent oxygen, and 82 mole percent NF₃, or 4.5 mole percent C₄F₈, 9 mole percent oxygen, and 86.5 mole percent NF₃. Total gas flow rate was 1700 sccm. The chamber pressure was 2 torr. The feeding gas was activated by the 400 kHz 6.5 Kw RF power to a neutral temperature of more than 3000 K. The results are illustrated in FIG. 9. Octafluorocyclobutane exhibited similar etching performance compared to hexafluoroethane with respect to etch rate, and variation with variations in source pressure.

### Example 8

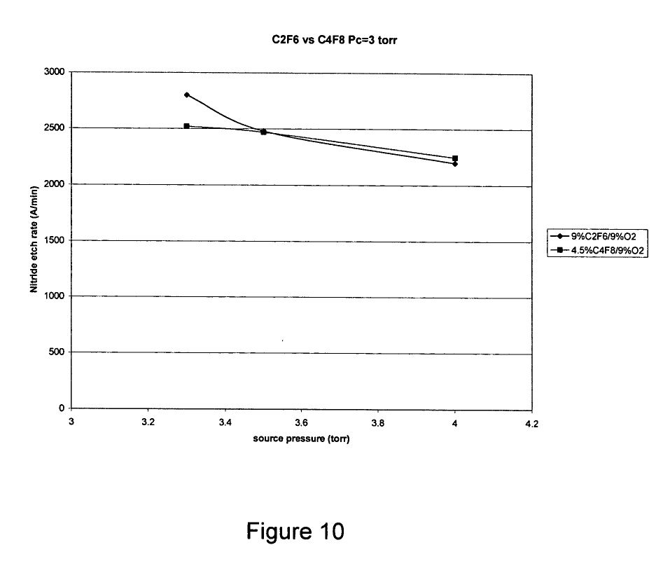

This example compares nitride etching using octafluorocyclobutane as the fluorocarbon. In this example, the feed gas mixtures were either 9 mole percent C₂F₆, 9 mole percent oxygen, and 82 mole percent NF₃, or 4.5 mole percent C₄F₈, 9 mole percent oxygen, and 86.5 mole percent NF₃. The chamber pressure was 3 torr. Total gas flow rate was 1700 sccm. The feeding gas was activated by the 400 kHz 6.9 Kw RF power to a neutral temperature of more than 3000 K. The results are illustrated in FIG. 10. Octafluorocyclobutane exhibited similar etching performance compared to hexafluoroethane with respect to etch rate, and variation with variations in source pressure.

### Example 9

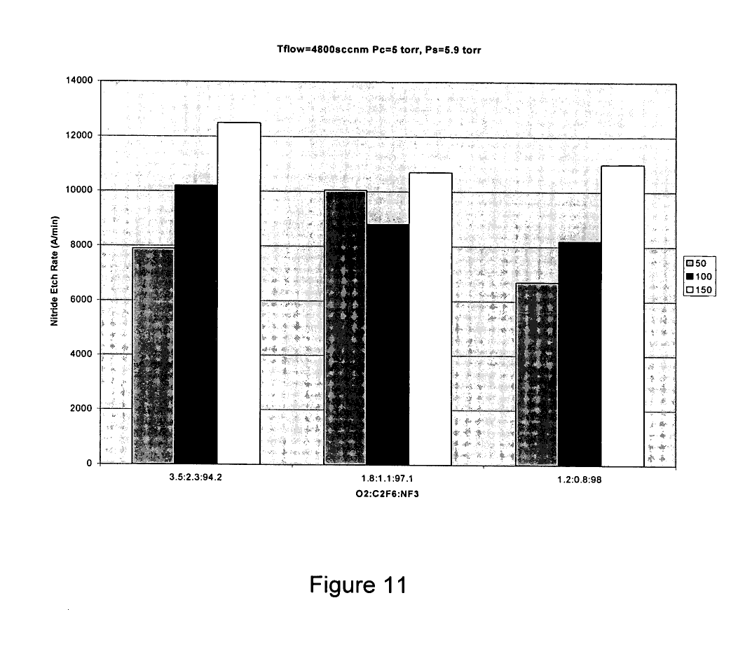

This example illustrates the effect of the addition of fluorocarbon on the silicon nitride etch rate in NF₃ systems with oxygen at different gas compositions and different wafer temperatures. In this experiment, the feed gas was composed of NF₃, with oxygen and C₂F₆. Process chamber pressure was 5 torr. Total gas flow rate was 4800 sccm, with flow rates for the individual gases set proportionally as required for each experiment. By way of illustration, in the experiment with 1.8% oxygen, 1.1% C₂F₆, and 97.1% NF₃, the oxygen flow rate was 85 sccm, the C₂F₆ flow rate was 50 sccm, and the NF₃ flow rate was 4665 sccm. The feeding gas was activated by the 400 kHz 5-8 kW RF power. The activated gas then entered the process chamber and etched the silicon nitride surface deposits on the mounting with the temperature controlled at 50° C. As shown in FIG. 11, when 3.5 mole percent oxygen and 2.3 mole percent fluorocarbon were added, the etch rate was over 7500 A/min, and exhibited low sensitivity to variations in the amounts of fluorocarbon and oxygen addition. The same phenomena were observed in all wafer temperatures tested: 50° C., 100° C. and 150° C. Even at 1.2 mole % O₂ and 0.8 mole % C₂F₆, high etch rates were observed.

### Example 10

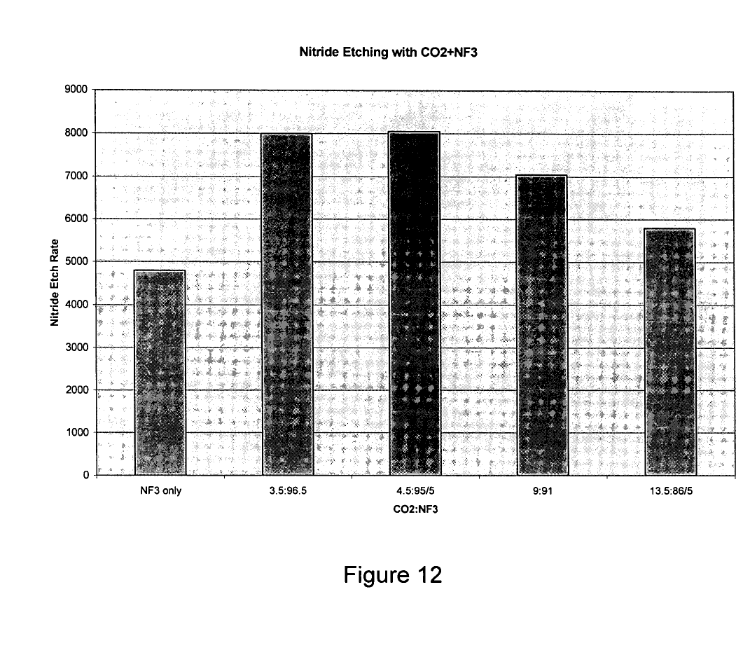

This example illustrates the use of carbon dioxide as a carbon source and oxygen source etching silicon nitride with NF₃. Process chamber pressure was 5 torr. Total gas flow rate was 1700 sccm, with flow rates for the individual gases set proportionally as required for each experiment. By way of illustration, in the experiment with 4.5% CO₂, and 95.5% NF₃, the CO₂ flow rate was 75 sccm and the NF₃ flow rate was 1625 sccm. The feeding gas was activated by the 400 kHz 5-8 kW RF power. The activated gas then entered the process chamber and etched the silicon nitride surface deposits on the mounting with the temperature controlled at 50° C. As shown in FIG. 12, when 3.5% CO₂ was added, the etch rate was 8000 A/min. Etch rates higher than NF₃ alone were observed for up to 13.5% CO₂.

### Example 11

This example compares CH₄ and C₂F₆ as carbon sources in nitride etching experiments in NF₃ systems with oxygen at different gas compositions. In this experiment, the feed gas was composed of NF₃, with oxygen and carbon source. Process chamber pressure was 5 torr. Total gas flow rate was 1700 sccm, with flow rates for the individual gases set proportionally as required for each experiment. By way of illustration, in the experiment with 4.5% oxygen, 4.5% C₂F₆, and 91% NF₃, the oxygen flow rate was 75 sccm, the C₂F₆ flow rate was 75 sccm, and the NF₃ flow rate was 1550 sccm. The feeding gas was activated by the 400 kHz 5-8 kW RF power. The activated gas then entered the process chamber and etched the silicon nitride surface deposits on the mounting with the temperature controlled at 50° C. As shown in FIG. 13, with 2.3 or 4.5% CH₄, etch rates superior to C₂F₆ were obtained. However, with 4.5% CH₄, the silicon nitride etch rate decreased with time in the experiment.

### Example 12

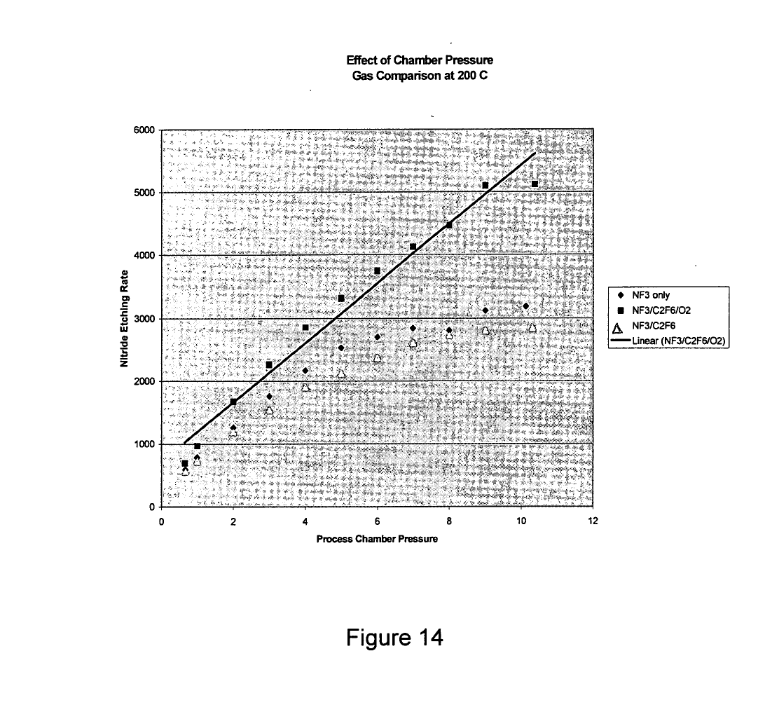

This example compares a blend of NF₃/C₂F₆/O₂ (82/9/9) with NF₃ alone and NF₃ plus C₂F₆ with a wafer temperature of 200° C. Chamber pressures were varied from 0.7 torr to 10 torr. The pressure at the remote source was about 15 torr. Total gas flow rate was 4800 sccm, with flow rates for the individual gasses set proportionally as required for each experiment. For this experiment, the valve (104) as illustrated in FIG. 2 was replaced with an orifice that was operated in choked flow so that the source pressure remained essentially constant while the chamber pressure was varied. As shown in FIG. 14, with a mixture of NF₃/C₂F₆/O₂ etch rate increase roughly linearly with increasing process chamber pressures, while with NF₃ alone or NF₃+C₂F₆, etch rate leveled off as pressures increased, indicating increased recombination at higher pressures.

### Example 13

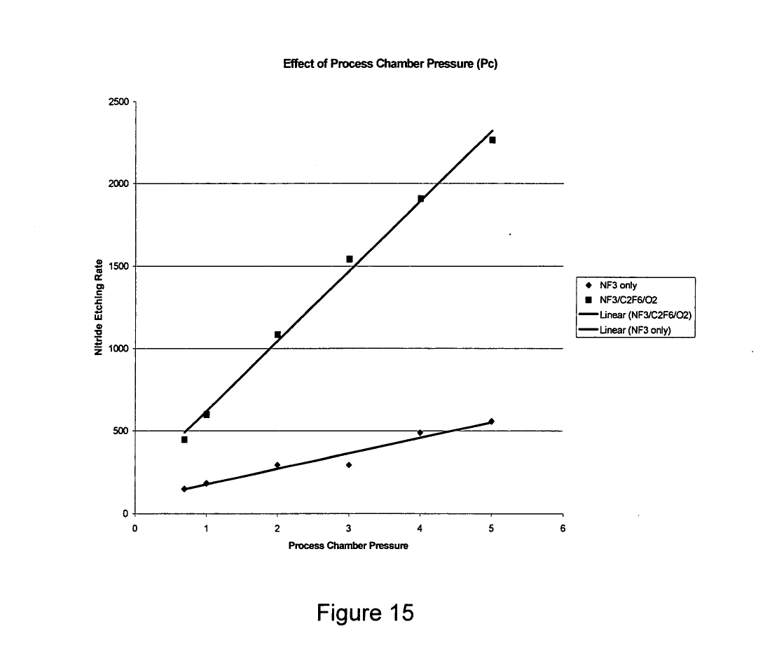

This example compares a blend of NF₃/C₂F₆/O₂ (82/9/9) with NF₃ with a wafer temperature of 100° C. and chamber pressures from 0.7 torr to 5 torr. The pressure at the remote source was about 15 torr. Total gas flow rate was 4800 sccm, with flow rates for the individual gasses set proportionally as required for each experiment. For this experiment, the valve (104) as illustrated in FIG. 2 was replaced with an orifice that was operated in choked flow so that the source pressure remained essentially constant while the chamber pressure was varied. As shown in FIG. 15, the nitride etch rate using a blend of NF₃/C₂F₆/O₂ is roughly 3 to 4 times that observed with NF₃ alone, and increases with increasing chamber pressure.

While specific embodiments of the invention have been shown and described, further modifications will occur to those skilled in the art. The present invention may be embodied in other specific forms without departing from the spirit or essential attributes thereof and, accordingly, reference should be made to the appended claims, rather than to the foregoing specification, as indicating the scope of the invention.

What is claimed is:

1. An activated gas mixture comprising:
from about 60% to about 75%, fluorine atoms,
from about 10% to about 30% nitrogen atoms,
optionally, up to about 15% oxygen atoms, and
from about 0.3% to about 15% of one or more atoms selected from the group consisting of carbon and sulfur.

2. An activated gas mixture as in claim 1 wherein the percentage of fluorine atoms is from about 66% to about 74%,
the percentage of nitrogen atoms is from about 11% to about 24%,
the percentage of oxygen atoms is from about 0.9% to about 11%, and
the percentage of one or more atoms selected from the group consisting of carbon and sulfur is from about 0.6% to about 11%.

3. An activated gas mixture as in claim 1 wherein the one or more atoms selected from the group consisting of carbon and sulfur is carbon.

4. An activated gas mixture as in claim 1 further comprising a carrier gas.

5. An activated gas mixture as in claim 4 wherein the carrier gas is selected from the group consisting of argon and helium.

6. An activated gas mixture as in claim 5 wherein the carrier gas is argon.

7. A process for etching and removing surface deposits on the interior surfaces of a CVD apparatus, comprising: activating in a remote chamber a gas mixture comprising an oxygen source, a source of one or more atoms selected from the group consisting of carbon and sulfur, and NF₃, wherein the molar ratio of oxygen source:source of one or more atoms selected from the group consisting of carbon and sulfur is at least about 0.75:1, and wherein the molar percentage of NF₃ in the said gas mixture is from about 50% to about 98%; allowing said activated gas mixture to flow through a conduit and into a process chamber, thereby reducing the rate of surface recombination of gas phase species on the interior surfaces of said CVD apparatus.

8. A process as in claim 7 wherein the one or more atoms selected from the group consisting of carbon and sulfur is carbon.

9. A process as in claim 7 wherein the apparatus is a PECVD apparatus.

10. A process as in claim 7 wherein the interior surfaces of the apparatus are constructed from a material selected from the group consisting of aluminum and anodized aluminum.

11. A process as in claim 7 wherein the conduit is cooled.

12. A process as in claim 7 wherein a throttle valve is used to increase the pressure in the apparatus during the cleaning cycle.

13. A process as in claim 8 wherein the oxygen source is molecular oxygen.

14. A process as in claim 8 wherein the carbon source is a fluorocarbon.

15. A process as in claim 14 wherein the fluorocarbon is a perfluorocarbon.

16. A process as in claim 14 wherein the fluorocarbon is selected from the group consisting of tetrafluoromethane, hexafluoroethane, octafluoropropane, perfluorotetrahydrofuran, and octafluorocyclobutane.

17. A process as in claim 14 wherein the fluorocarbon is hexafluoroethane.

18. A process as in claim 14 wherein the fluorocarbon is octafluorocyclobutane.

19. A process as in claim 7 wherein the molar percentage of NF₃ is from about 60% to about 98% of the gas mixture.

20. A process as in claim 7 wherein the NF₃ is from about 70% to about 90% of the gas mixture.

21. A process as in claim 14 wherein the oxygen source:carbon source ratio is about 1:1.

22. A process as in claim 14 wherein the oxygen source and the carbon source are carbon dioxide and the molar percentage of carbon dioxide in the gas mixture is from about 2% to about 15%.

23. A process as in claim 7 wherein the gas mixture further comprises a carrier gas.

24. A process as in claim 23 wherein said carrier gas is selected from the group consisting of argon and helium.

25. A process as in claim 7 wherein the pressure in the process chamber is from about 0.5 torr to about 20 torr.

26. A process as in claim 7 wherein the pressure in the process chamber is from about 1 torr to about 15 torr.

27. A process as in claim 7 wherein the pressure in the remote chamber is from about 0.5 torr to about 15 torr.

28. A process as in claim 27 wherein the pressure in the remote chamber is from about 2 torr to about 6 torr

29. A process in claim 7 wherein said power is generated by an RF source, a DC source or a microwave source.

30. A process as in claim 29 wherein said power is generated by an RF source.

31. A process of passivating the interior surfaces of an apparatus comprising:
(a) producing an activated gas mixture of claim 1 in a remote chamber,
(b) allowing said activated gas mixture to flow through a conduit and into a process chamber, and thereafter,
(c) reducing the rate of surface recombination of gas phase species.

32. A process as in claim 31 wherein the apparatus is a PECVD apparatus.

33. A process as in claim 31 wherein the interior surfaces of the apparatus are constructed from a material selected from the group consisting of aluminum and anodized aluminum.

34. A process as in claim 31 wherein the conduit is cooled.

35. A process as in claim 31 wherein a throttle valve is used to increase the pressure in the apparatus during the cleaning cycle.

36. A process as in claim 31 wherein the gas mixture further comprises a carrier gas.

37. A process as in claim 36 wherein said carrier gas is selected from the group consisting of argon and helium.

38. A process as in claim 31 wherein the pressure in the process chamber is from about 0.5 torr to about 20 torr.

39. A process as in claim 31 wherein the pressure in the process chamber is from about 1 torr to about 15 torr.

40. A process as in claim 31 wherein the pressure in the remote chamber is from about 0.5 torr to about 15 torr.

41. A process as in claim 31 wherein the pressure in the remote chamber is from about 2 torr to about 6 torr

42. A process in claim 31 wherein said power is generated by an RF source, a DC source or a microwave source.

43. A process as in claim 42 wherein said power is generated by an RF source.

44. A PECVD apparatus comprising:
(a) a remote plasma source chamber,
(b) a gas distribution system connecting the remote plasma source to supplies of a cleaning gas and an inert gas,
(c) a PECVD chamber wherein the remote plasma chamber is coupled to the PECVD chamber by a means allowing for transfer of an activated gas according to claims 1, 2, 3, or 4, from the remote plasma chamber to the process chamber, and
(d) an exhaust line.

45. A PECVD apparatus as in claim 44 wherein the exhaust line is connected to a vacuum source.

46. A PECVD apparatus as in claim 45 wherein the vacuum source is a vacuum pump.

47. A PECVD apparatus as in claim 44 wherein the means allowing for transfer of the activated gas from the remote plasma chamber to the process chamber comprises a short connecting tube to a shower head and a direct conduit connecting the plasma source to the process chamber.

48. A PECVD apparatus as in claim 47 wherein the short connecting tube to the shower head and the direct conduit connecting the plasma source to the process chamber each further comprise a flow restricting device to vary the proportion of activated gas flowing through the two paths.

49. A PECVD apparatus as in claim 48 wherein the flow restricting device is an orifice or a valve.

50. A PECVD apparatus as in claim 44 wherein the exhaust line further comprises at least one throttle valve.

51. A PECVD apparatus as in claim 44 wherein the gas distribution system comprises piping connecting gas cylinders for each gas supplied to the PECVD chamber through individual mass flow controllers for each gas, into a mixing chamber and thence connected to the remote plasma source chamber.

52. A PECVD apparatus as in claim 44 wherein the gas distribution system comprises piping connecting a cylinder of a cleaning gas mixture through a mass flow controller into the remote plasma source chamber, and piping connecting a source of inert gas through a mass flow controller and into the remote plasma source chamber.

53. A PECVD apparatus as in claim 44 wherein the means allowing for transfer of the activated gas from the remote plasma chamber to the process chamber is cooled.

54. A PECVD apparatus as in claim 44 wherein the exhaust line piping is either aluminum or anodized aluminum and is cooled.

55. A gas mixture for cleaning a CVD reactor, comprising in molar percent of the gas,
up to 25% of an oxygen source gas,
from about 50% to about 98% of an inorganic fluorine source gas,
up to about 25% of a carbon source gas, and
up to about 25% of a sulfur source gas, wherein the combined amount of the carbon source gas plus the amount of the sulfur source gas is 1% to 25%.

56. The gas mixture of claim 55, wherein the inorganic fluorine source gas is NF₃.

57. The gas mixture of claim 55, wherein the carbon source gas is a fluorocarbon or a hydrocarbon.

58. The gas mixture of claim 57, wherein the carbon source gas is CO₂, CH₄, C₂F₈, or octofluorocyclobutane.

59. The gas mixture of claim 55, wherein the sulfur source gas is SF₆.

60. A cleaning gas mixture comprising from about 50% to about 98% on a molar basis NF₃, an oxygen source and a fluorocarbon.

61. A cleaning gas mixture as in claim 60 wherein the oxygen source is molecular oxygen.

62. A cleaning gas mixture as in claim 60 wherein the fluorocarbon is a perfluorocarbon.

63. A cleaning gas mixture as in claim 62 wherein the perfluorocarbon is selected from the group consisting of tetrafluoromethane, hexafluoroethane, octafluoropropane, perfluorotetrahydrofuran and octafluorocyclobutane.

64. A cleaning gas mixture as in claim 62 wherein the perfluorocarbon is hexafluoroethane.

65. A cleaning gas mixture as in claim 36 wherein the perfluorocarbon is octafluorocyclobutane.

66. A cleaning gas mixture as in claim 61 wherein the oxygen:fluorocarbon ratio is at least about 0.75:1.0.

67. A cleaning gas mixture as in claim 61 wherein the oxygen:fluorocarbon ratio is at least about 1:1.
